(19) United States
(12) Patent Application Publication
(10) Pub. No.: US 2025/0374570 A1
(43) Pub. Date: Dec. 4, 2025

(54) SEMICONDUCTOR TRANSMITTER WITH INDIRECTLY-PATTERNED EMITTER

(71) Applicant: Texas Instruments Incorporated, Dallas, TX (US)

(72) Inventor: Robert Cassel, Lehi, UT (US)

(73) Assignee: Texas Instruments Incorporated, Dallas, TX (US)

(21) Appl. No.: 18/731,016

(22) Filed: May 31, 2024

(51) Int. Cl. H01L 29/732; H01L 21/311; H01L 29/66

(52) U.S. Cl. CPC H10D 10/40; H01L 21/31144; H10D 10/01

(57) ABSTRACT

In one example, a method of forming an electronic device includes receiving a semiconductor substrate having a dielectric layer located over an emitter region of a partially formed bipolar junction transistor. A sacrificial layer is formed over the dielectric layer. A resist layer is formed over the sacrificial layer. A first pattern is formed in the resist layer including a resist layer sidewall over the emitter region. A second pattern is formed in the sacrificial layer. The second pattern includes a sacrificial layer sidewall aligned with the resist layer sidewall. The second pattern is transferred to the dielectric layer.

### RELATED APPLICATIONS

The present application is related to U.S. application Ser. Nos. 18/520,527, 18/608,669, 18/680,460, and 18/679,642, each of which is incorporated by reference herein in its entirety.

### BACKGROUND

Semiconductor components are being continually improved to reliably operate with smaller feature sizes. Fabricating semiconductor devices that have increasingly higher performance while meeting reliability specifications is challenging.

### SUMMARY

In one example, a method of forming an electronic device includes receiving a semiconductor substrate having a dielectric layer located over an emitter region of a partially formed bipolar junction transistor. A sacrificial layer is formed over the dielectric layer. A resist layer is formed over the sacrificial layer. A first pattern is formed in the resist layer including a resist layer sidewall over the emitter region. A second pattern is formed in the sacrificial layer. The second pattern includes a sacrificial layer sidewall aligned with the resist layer sidewall. The second pattern is transferred to the dielectric layer.

In another example, an integrated circuit includes a semiconductor substrate and a bipolar junction transistor over the substrate. The bipolar junction transistor has a collector having a first conductivity type over the substrate, and a base having an opposite second conductivity type over the collector. A dielectric layer extends over the base. An emitter is over the base and extends through an opening in the dielectric layer. The emitter has first and second ends. A pattern extends from one or both of the first and second ends. The pattern includes an edge extending laterally over the semiconductor substrate.

In another example, a method of forming an integrated circuit includes forming a material stack over a substrate including a first doped region having a first conductivity type located over a second doped region having a second conductivity type. The material stack includes a first material layer, a second material layer over the first material layer, and a third material layer over the second material layer. A first opening is formed through the third material layer, the first opening having a sidewall over the first doped region. A fourth material layer is formed over the third material layer and extending into the opening, a sidewall portion of the fourth material layer located over the sidewall. A fifth material layer is formed within the opening, the sidewall portion between the sidewall and the fifth material layer. The sidewall portion is removed, thereby forming a second opening over the first doped region.

### BRIEF DESCRIPTION OF THE DRAWINGS

FIGS. 1 through 10 are respective cross-sectional views of a portion of a semiconductor device at intermediate stages of manufacturing according to some examples.

FIGS. 11 through 13 are top-down views of the semiconductor device of FIGS. 1-10 at intermediate stages of manufacturing according to some examples.

FIGS. 14 through 20 are respective cross-sectional views of a portion of the semiconductor device of FIGS. 1-3 at intermediate stages of manufacturing according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. Other examples may include any permutation of including or excluding aspects or features that are described. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to semiconductor processing integration for a bipolar junction transistor (BJT). Some examples include a semiconductor device including a BJT over a semiconductor substrate. The BJT has a collector and a base on or over the collector. A dielectric layer extends over the base. An emitter is over the base and extends through an opening in the dielectric layer. The emitter has first and second ends. A pattern extends from one or both of the first and second ends. The pattern includes an edge extending laterally over the semiconductor substrate. Semiconductor processing to form example BJTs disclosed herein may enable vertical and horizontal scaling of the BJT, which may improve performance characteristics (e.g., parasitic resistances and capacitances) of the BJT while simplifying production and reducing production costs. Other benefits and advantages may be achieved.

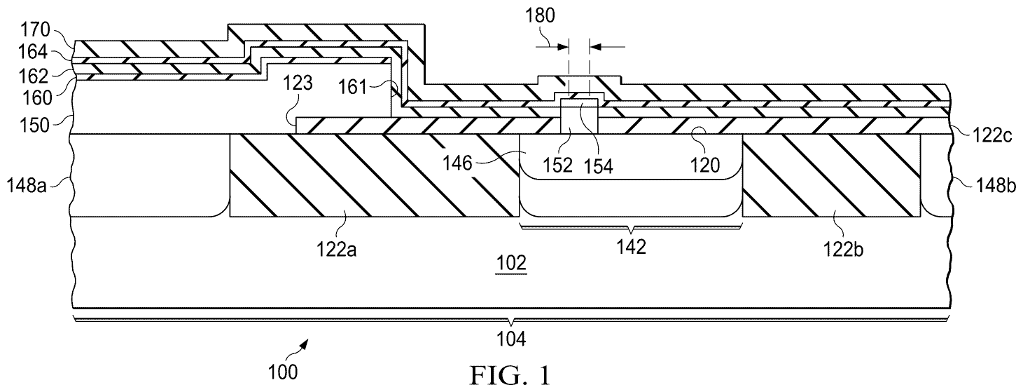

FIGS. 1 through 10 are respective cross-sectional views of a portion of a semiconductor device 100 at intermediate stages of manufacturing according to some examples. Additional detail concerning certain features of a BJT corresponding to that shown in FIG. 1 of the instant disclosure, and methods of fabricating the same, are disclosed in related applications U.S. application Ser. Nos. 18/520,527, 18/608,669, 18/680,460, and 18/679,642. The example intermediate stages shown in FIGS. 1 through 10 illustrate the transfer of a pattern to dielectric spacer layer 170, in which a portion of the transferred pattern has a critical dimension (CD) 180 that is useable in forming a portion of an emitter of a BJT.

The CD 180 is a dimension that is deemed “critical” in that its line width roughness (LWR) may significantly impact transistor performance metrics, such as the unity current gain frequency (fT) and the maximum oscillation frequency (fmax) of the transistor. Conventional semiconductor processing techniques, including various patterning methods, have limited capabilities in achieving sufficiently low LWR for certain CD ranges (e.g., 20 nanometers or less). For example, some conventional photo patterning capabilities have a three sigma LWR of 2-4 nanometers at dimensions of 20 nanometers or less. Such roughness may negatively impact transistor performance, device yield, or both. Thus, a solution is needed to improve the LWR achieved for a CD that is 20 nanometers or less, in which the CD is useable in forming a portion of a BJT emitter.

Referring to FIG. 1, a semiconductor substrate 102 is provided having a BJT region 104. The semiconductor substrate 102 may be or include a bulk semiconductor substrate, a semiconductor-on-insulator (SOI) substrate, or any other appropriate substrate. The semiconductor substrate 102 may also include a support (or handle) substrate and an epitaxial layer epitaxially grown on the support substrate. In some examples, the semiconductor substrate 102 is or includes a silicon substrate (which may be singulated from a bulk silicon wafer at the conclusion of semiconductor processing). In further examples, the semiconductor substrate 102 includes a silicon substrate with an epitaxial silicon layer grown thereon. The semiconductor substrate 102 is or includes semiconductor material formed therein or thereon. The semiconductor substrate 102 has an upper surface 120 over which certain features of a BJT are formed. In some examples, the semiconductor material is or includes silicon (Si), silicon germanium (SiGe), gallium arsenide (GaAs), gallium nitride (GaN), the like, or a combination thereof. In some examples, certain semiconductor material of the semiconductor substrate 102 can be p-doped with a p-type dopant (e.g., boron (B)) with a concentration in a range from 1×10¹⁴ cm⁻³ to 1×10¹⁵ cm⁻³. Another dopant type or other doping concentrations may be implemented.

Isolation structure 122 is formed over or extending into semiconductor substrate 102. Isolation structure 122 laterally surrounds and caps an active area of the upper surface 120 of the semiconductor substrate 102 on which the BJT is to be formed. Isolation structure 122 may include three portions 122a, 122b, 122c. The first and second isolation structure portions 122a, 122b are both shallow trench isolation structures (STIs) extending from the upper surface 120 of the semiconductor substrate 102 into the semiconductor substrate 102. The third isolation structure portion 122c extends upward from the upper surface 120 of the semiconductor substrate 102 and may structurally provide a BJT pedestal. In other examples, the isolation structure portions 122a, 122b, 122c may have respective upper surfaces co-planar with and/or below the upper surface 120 of the semiconductor substrate 102. Isolation structure 122 may include, for example, a liner layer, such as including silicon oxide or silicon nitride, conformally along surfaces of a respective trench in the semiconductor substrate 102 and a fill isolation material, such as silicon oxide, over and on the liner layer. In some examples, at least a portion of isolation structure 122 is formed by depositing silicon oxide.

Isolation structure portions 122a, 122b, as illustrated, may be formed by depositing a hardmask layer over the semiconductor substrate 102. The hardmask layer may be any appropriate material, such as silicon nitride, silicon oxynitride, or the like, and may be deposited using any appropriate deposition process, such as chemical vapor deposition (CVD). The hardmask layer is patterned, such as by using photolithography and an etching process (e.g., reactive ion etch (RIE)). Recesses or trenches are etched, such as by RIE, in the semiconductor substrate 102 using the patterned hardmask layer as a mask. The liner layer may then be conformally deposited in the recesses or trenches and over the patterned hardmask layer (or formed on exposed surfaces of the recesses or trenches—e.g., by an oxidation process), such as by plasma enhanced CVD (PECVD), and the fill isolation material may be deposited over the liner layer, such as by high aspect ratio CVD (HAR-CVD), flowable CVD (FCVD), or the like. Excess fill isolation material and liner layer may be removed from over the hardmask layer by a planarization process, such as a chemical mechanical polish (CMP). The hardmask layer may then be removed by an etch selective to the hardmask layer, which may be a wet etch process. In other examples, the isolation structure 122 may be field oxide structures, such as local oxidation of silicon (LOCOS) structures, at the upper surface 120 of the semiconductor substrate 102, which may be formed using a LOCOS process.

An n-type doped well 142 is formed in the semiconductor substrate 102. The well 142 may be formed by masking (e.g., by a photoresist using photolithography) areas of the semiconductor substrate 102 where the well is not to be formed and implanting n-type dopants into the semiconductor substrate 102. The well 142 extends from the upper surface 120 of the semiconductor substrate 102 into a depth in the semiconductor substrate 102 and is in the BJT region 104 laterally between the portions 122a, 122b of the isolation structure 122. A concentration of the n-type dopant of the well 142 is greater than a concentration of the p-type dopant of the p-type doped semiconductor substrate 102. In some examples, the well 142 is doped with an n-type dopant (e.g., phosphorus (P) or arsenic (As)) with a concentration in a range from 1×10¹⁵ cm⁻³ to 1×10¹⁷ cm⁻³. Another dopant type and/or other doping concentrations may be implemented.

An n-type doped sub-collector diffusion region 146 is formed in the semiconductor substrate 102 in the well 142. The sub-collector diffusion region 146 may be formed by masking (e.g., by a photoresist using photolithography) areas of the semiconductor substrate 102 where a sub-collector diffusion region 146 is not to be formed and implanting n-type dopants into the semiconductor substrate 102. The sub-collector diffusion region 146 extends from the upper surface 120 of the semiconductor substrate 102 into a depth in the well 142 in the semiconductor substrate 102 and is in the BJT region 104 laterally between the portions 122a, 122b of the isolation structure 122. A dopant concentration of the sub-collector diffusion region 146 is greater than the concentration of the n-type dopant of the n-type dopant of the remainder of the well 142. In some examples, the sub-collector diffusion region 146 is doped with an n-type dopant with a concentration in a range from 1×10¹⁸ cm⁻³ to 1×10²⁰ cm⁻³. Another dopant type and/or other doping concentrations may be implemented.

Although the well 142 and the sub-collector diffusion region 146 are described herein as being doped with a certain dopant conductivity type, such components may be doped with an opposite conductivity type (e.g., being p-type doped instead of n-type doped, and vice versa) in other examples. Similarly, subsequently described components that are described as being doped with a certain dopant conductivity type may also be doped with an opposite conductivity type in other examples.

In some examples and as illustrated, a p-type doped well 148 (shown in FIG. 1 as p-type doped well portions 148a, 148b) is formed in the semiconductor substrate 102. The p-type doped well 148 may be formed by masking (e.g., by a photoresist using photolithography) areas of the semiconductor substrate 102 where a p-type doped well is not to be formed and implanting p-type dopants into the semiconductor substrate 102. The p-type doped well 148 extends from the upper surface 120 of the semiconductor substrate 102 into a depth in the semiconductor substrate 102 and is in the BJT region 104 laterally adjacent to isolation structure portions 122a, 122b. The illustrated portions 148a, 148b of p-type doped well 148 may be part of a continuous isolation frame enclosing the active area in which the BJT is to be formed. A concentration of the p-type dopant of the p-type doped well 148 is greater than a concentration of the p-type dopant of the p-type doped semiconductor substrate 102. In some examples, the p-type doped well 148 is doped with a p-type dopant (e.g., boron (B)) with a concentration in a range from 1×10¹⁵ cm³ to 1×10¹⁷ cm³. Another dopant type and/or other doping concentrations may be implemented.

Isolation structure portion 122c is formed over the upper surface 120 of the semiconductor substrate 102, including on the first and second portions of isolation structures 122a, 122b and on the sub-collector diffusion region 146. In some examples, isolation structure portion 122c is formed by conformally depositing (e.g., by CVD) silicon oxide (e.g., a tetraethyl orthosilicate (TEOS) oxide), although other dielectric materials and/or other deposition processes may be used in other examples.

As shown in FIG. 1, isolation structure portion 122c has a pattern extending laterally across a portion of the BJT region 104. More specifically, the isolation structure portion 122c is over the upper surface 120 of the semiconductor substrate 102 in the BJT region 104 and extends laterally such that a sidewall 123 of the isolation structure portion 122c is positioned over the upper surface 120 of the semiconductor substrate 102 on the isolation structure portion 122a. The illustrated pattern of isolation structure portion 122c may be effected, for example, using appropriate photolithography and etching processes. For example, an anisotropic etch, such as an RIE, may be implemented.

In some examples, a CMOS gate layer 150 is formed over the semiconductor substrate 102, and a dielectric layer 160 is formed over the layer 150. The CMOS gate layer 150 can be or can include a semiconductor material, such as polycrystalline silicon (polysilicon), and may be formed by any appropriate deposition process, such as CVD. The semiconductor material may be doped in situ during deposition and/or may be implanted with a dopant after deposition. The CMOS gate layer 150 can be polysilicon doped with a p-type dopant with a concentration in a range from 1×10¹⁹ cm⁻³ to 1×10²¹ cm⁻³ after deposition and/or implantation. The CMOS gate layer 150 may implemented by other conductive materials formed by any suitable deposition process. In some examples, the dielectric layer 160 is silicon oxide (e.g., a TEOS oxide) deposited by CVD, although other dielectric materials and/or other deposition processes may be used in other examples. In some examples, a gate oxide (not explicitly shown) having a thickness of 10 to 20 angstroms may be formed between CMOS gate layer 150 and respective portions of p-type doped well portion 148a and isolation structure portion 122a.

As shown in FIG. 1, the dielectric layer 160 and the CMOS gate layer 150 have been etched to form an opening that exposes the illustrated portion of isolation structure portion 122c in the BJT region 104, which is positioned on respective portions of isolation structure portions 122a, 122b and on the sub-collector diffusion region 146. The opening in the CMOS gate layer 150 is defined in part by a sidewall 161 of the CMOS gate layer 150, which is over the pedestal isolation structure portions 122a, 122c in the BJT region 104. The dielectric layer 160 and gate layer 150 may be etched using appropriate photolithography and etching processes. For example, an anisotropic etch, such as an RIE, may be implemented.

A BJT collector 152 is formed on or over the upper surface 120 of the semiconductor substrate 102. The BJT collector 152 is positioned on or over the n-type doped sub-collector diffusion region 146. In some examples, the BJT collector 152 is or includes silicon. In some examples, the material used to form BJT collector 152 is doped with an n-type dopant with a concentration in a range from 1×10¹⁹ cm⁻³ to 1×10²¹ cm⁻³. BJT collector 152 may be epitaxially grown on the upper surface 120 of the semiconductor substrate 102 by a selective epitaxial growth process. Such epitaxial growth may result in the BJT collector 152 being monocrystalline. Further, the material used to form BJT collector 152 may be in situ doped during the epitaxial growth process. The epitaxial growth process may be a CVD process, such as a low-pressure CVD (LPCVD), reduced pressure CVD (RPCVD), metal organic CVD (MOCVD), or the like. Other materials, dopant type, dopant concentration, and/or deposition process may be implemented.

An intrinsic base layer 162 is formed on the semiconductor substrate 102, including on or over at least respective portions of the dielectric layer 160, the isolation structure portion 122c, and the BJT collector 152. The base layer 162 includes both monocrystalline and polycrystalline portions, with the monocrystalline portion forming a BJT base 154 on or over the BJT collector 152. In some examples, the base layer 162 is or includes a semiconductor layer doped with a p-type dopant (e.g., an opposite dopant type as the sub-collector diffusion region 146). In some examples, the base layer 162 is or includes silicon germanium. In some examples, the base layer 162 is doped with a p-type dopant with a concentration in a range from 1×10¹⁷ cm⁻³ to 1×10²¹ cm⁻³. The base layer 162 may also be doped with carbon (C) to prevent or reduce diffusion of the p-type dopant. The base layer 162 may be epitaxially grown on the BJT collector 152 and on the dielectric layer 160. The base layer 162 may be epitaxially grown by a non-selective epitaxial growth process in some examples. The non-selective epitaxial growth process grows monocrystalline outward from the BJT collector 152 and grows the polycrystalline on other amorphous or polycrystalline surfaces. The base layer 162 may be in situ doped during the epitaxial growth process. The base layer 162 may further include multiple sub-layers, such as a nucleation sub-layer of the same material as the BJT collector 152, an undoped sub-layer, a doped sub-layer, and a cap sub-layer of the same material of the emitter layer (formed subsequently). The epitaxial growth process may be a CVD process, such as LPCVD, RPCVD, MOCVD, or the like. Other materials, dopant type, dopant concentration, and/or deposition process may be implemented.

One or more dielectric protective layer(s) 164 are formed conformally over base layer 162. In some examples, each dielectric protective layer 164 is or includes silicon oxide (e.g., a TEOS oxide) or silicon nitride. The dielectric protective layer(s) 164 may be deposited by CVD, for example. Other dielectric materials or formation processes may be used in other examples.

A dielectric spacer layer 170 is formed conformally over the dielectric protective layer(s) 164. In some examples, the dielectric spacer layer 170 is or includes silicon nitride. The dielectric spacer layer 170 may be deposited by CVD, for example. Other dielectric materials or formation processes may be used in other examples.

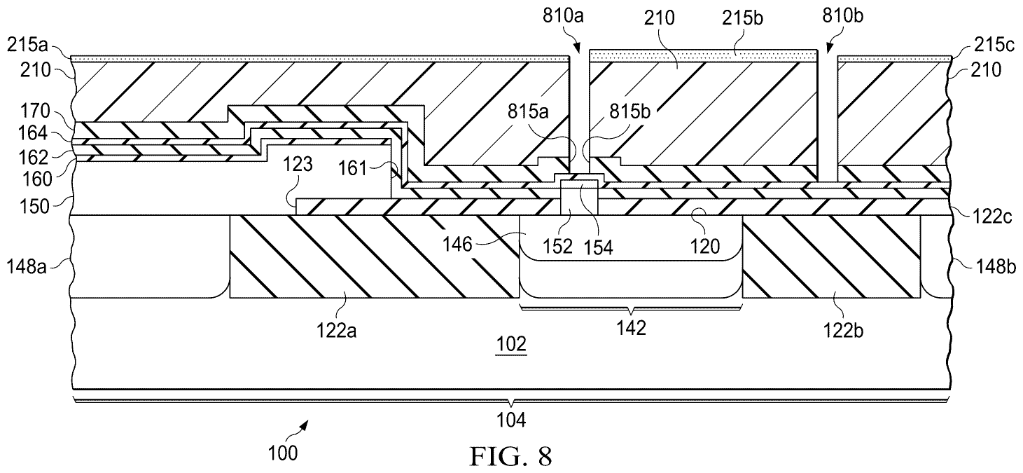

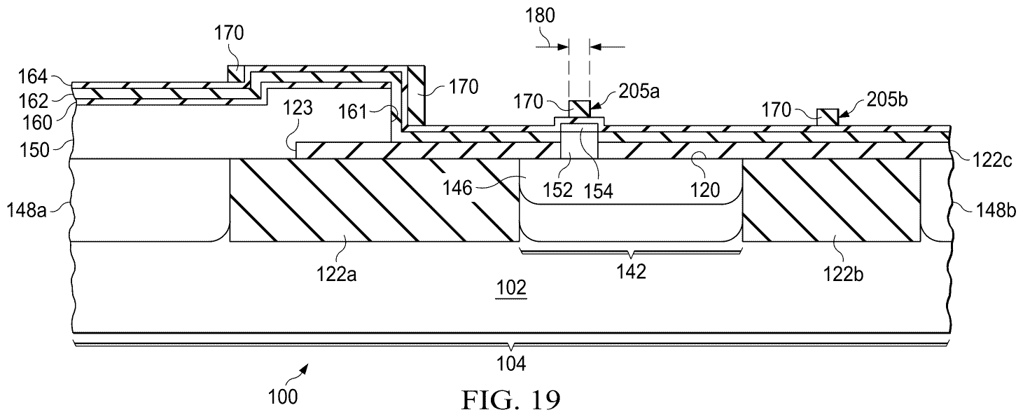

As stated above, CD 180 represents a desired width of a pattern that may be transferred to dielectric layer 170. The transferred pattern may be useable in forming a portion of a BJT emitter, for example. Any of a variety of process flows may be used to transfer the appropriate pattern to the dielectric spacer layer 170 having CD 180. In some examples, including those described with reference to FIGS. 1 through 10, CD 180 defines the width of an opening (e.g., opening 810a of FIG. 8) patterned in dielectric layer 170. In some examples, including those described with reference to FIGS. 1 through 3 and 14 through 19, CD 180 defines the width of a solid line (e.g., strip 205a of FIG. 19) patterned in dielectric layer 170. Regardless of whether the transferred pattern is used to form an opening or a solid line in dielectric layer 170, CD 180 may have a three-sigma LWR less than 4 nanometers.

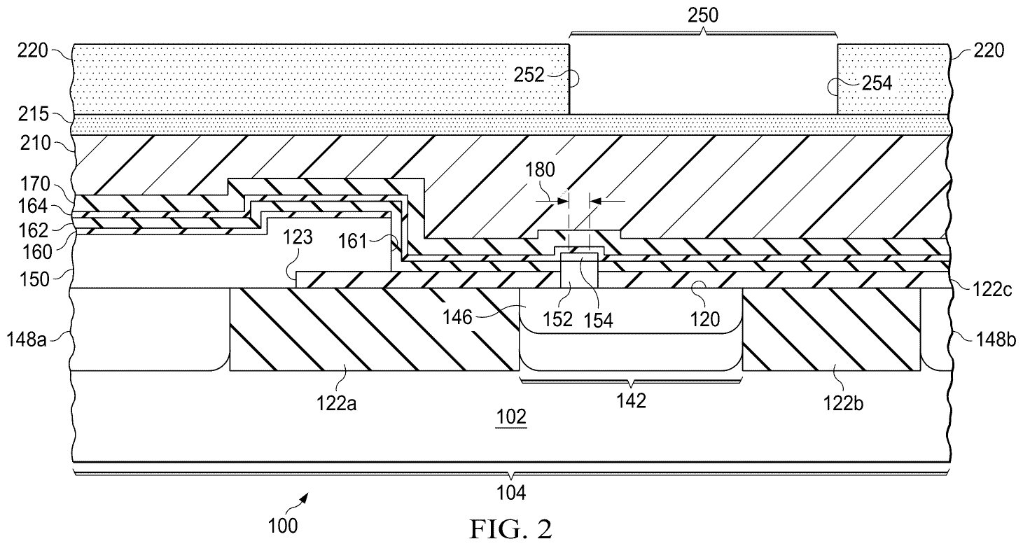

Referring to FIG. 2, a first sacrificial layer 210 is formed on dielectric spacer layer 170, a second sacrificial layer 215 is formed on the first sacrificial layer 210, and a resist layer 220 is formed on the second sacrificial layer 215. A combination of layers such as the layers 210, 215 and 220 is sometimes referred to as a trilayer resist. The first sacrificial layer 210 may be or may include a spin-on photolithography film that is carbon-based, such as CVD or another carbon-based hardmask stack, that provides appropriate selectivity for the sidewall patterning technique described herein. The second sacrificial layer 215 may be or include a dielectric anti-reflective coating (DARC) or a silicon-containing hard mask BARC (SHB), for example, The resist layer 220 may be or include a photoresist or an anti-reflective coating (ARC), for example.

The resist layer 220 is shown as having been patterned and selectively etched to form an opening 250 therein. In this example, the opening 250 has four contiguous sidewalls collectively forming a rectangular edge or mandrel. A first sidewall 252 of opening 250 is aligned with a line edge of CD 180, and hence aligned with an intended edge of an emitter portion of the BJT. In addition, the opening 250 has a second sidewall 254 parallel to the first sidewall 252.

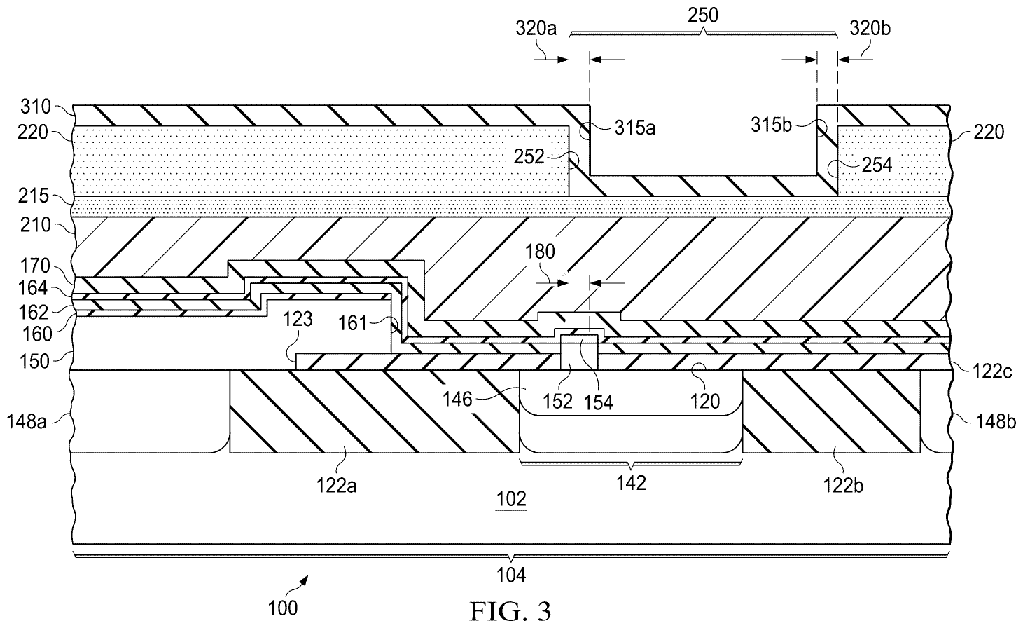

Referring to FIG. 3, a spacer layer 310 is formed conformally over resist layer 220, including within opening 250. In some examples, the spacer layer 310 may be or may include an oxide (e.g., silicon oxide). Spacer layer 310 includes portions having sidewalls 315a, 315b lining opposing sides of the opening 250. Sidewall 315a is spaced apart from sidewall 252 of resist layer 220, such that the thickness of the spacer layer 310 lining opening 250 is represented by thicknesses 320a, 320b. The thickness 320a is selected such that the sidewalls 252 and 315a align with corresponding respective edges of CD 180, such that the thickness 320a of spacer layer 310 is equivalent to (or is substantially equivalent to) CD 180

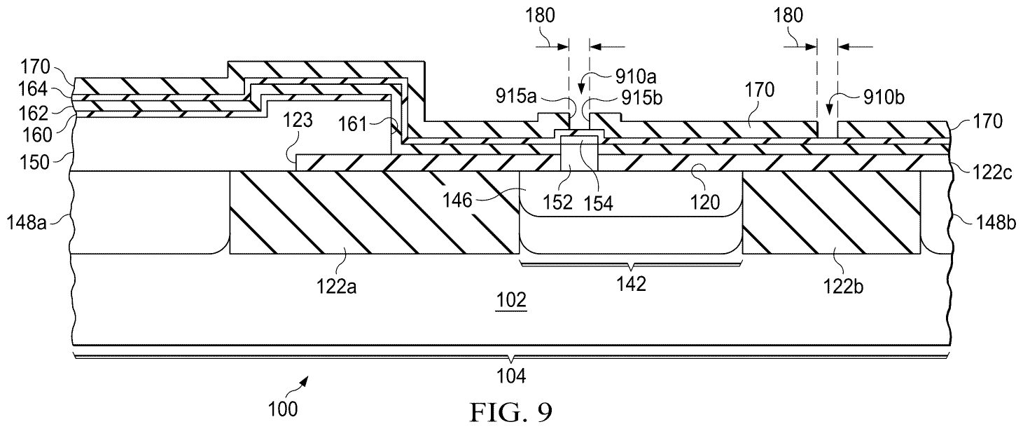

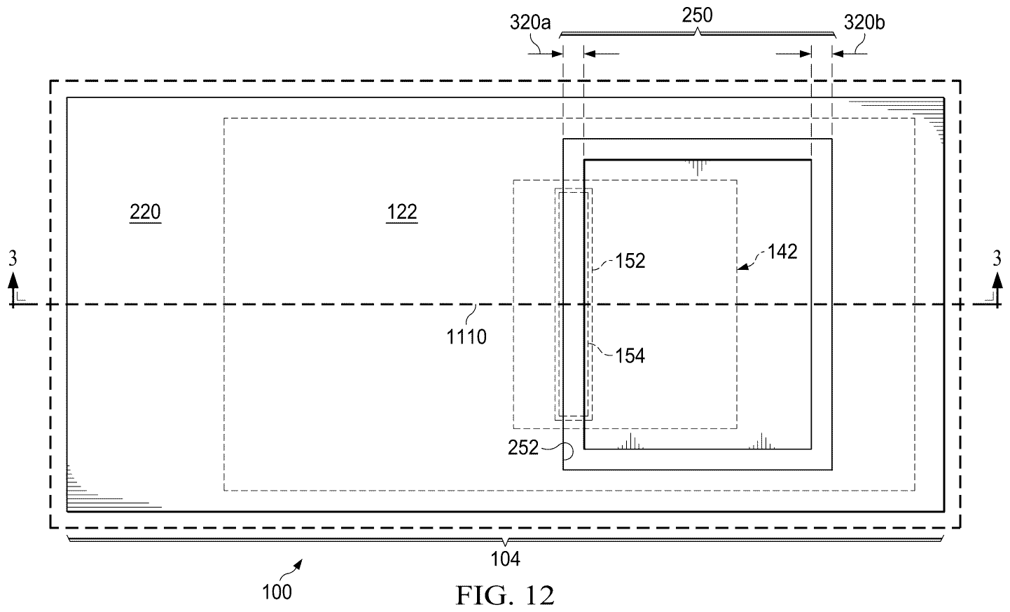

In some examples, from a top-down perspective (e.g., as shown in FIG. 12), spacer layer 310 lines all the sidewalls of opening 250 with a rectangular frame having a consistent width 320 along four contiguous strips. As explained subsequently, the frame-like pattern of spacer layer 310 lining the sidewalls of opening 250 may be transferred to underlying layers including dielectric spacer layer 170, for example. The transferred pattern may result in patterned edges that have a three-sigma LWR less than 4 nanometers. In some examples, the transferred pattern may be used to form an opening (e.g., opening 910a of FIG. 9) extending through underlying layers (e.g., dielectric spacer layer 170), in which the opening has the desired CD 180 at a position corresponding to an emitter region of a BJT. In some examples, the transferred pattern may be used to form a solid pattern (e.g., strip 205a of FIG. 19) in underlying layers (e.g., dielectric layers 164, 170), in which the solid pattern has the desired CD 180 at a position corresponding to an emitter region of a BJT.

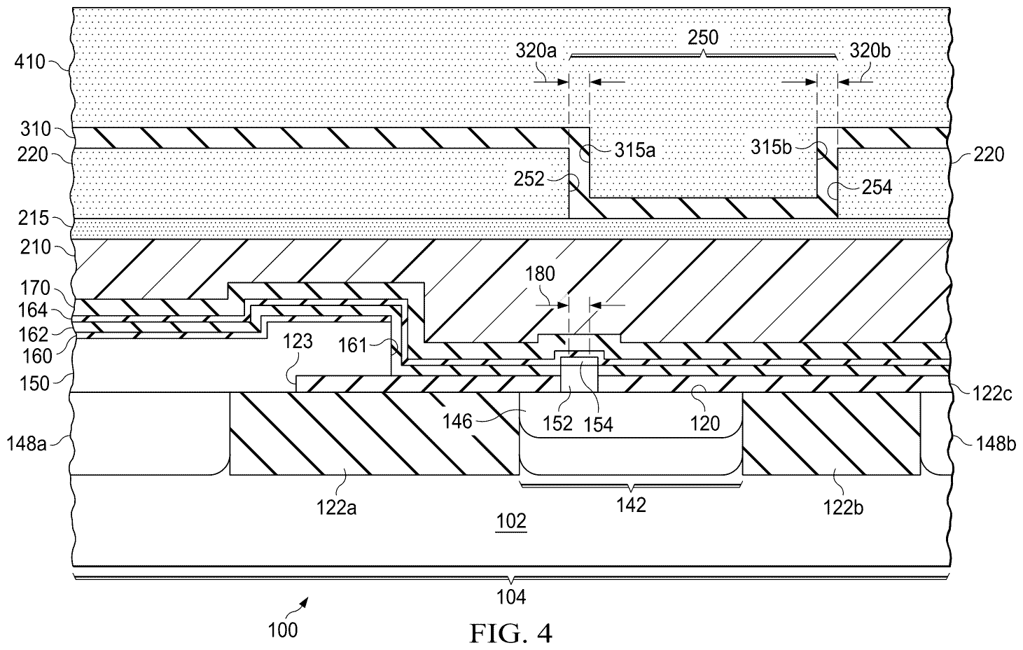

Referring to FIG. 4, a sacrificial layer 410 is formed over spacer layer 310 with sufficient thickness to completely fill the remainder of the opening 250 in resist layer 220. In some examples, the sacrificial layer 410 may be or include a photoresist or ARC.

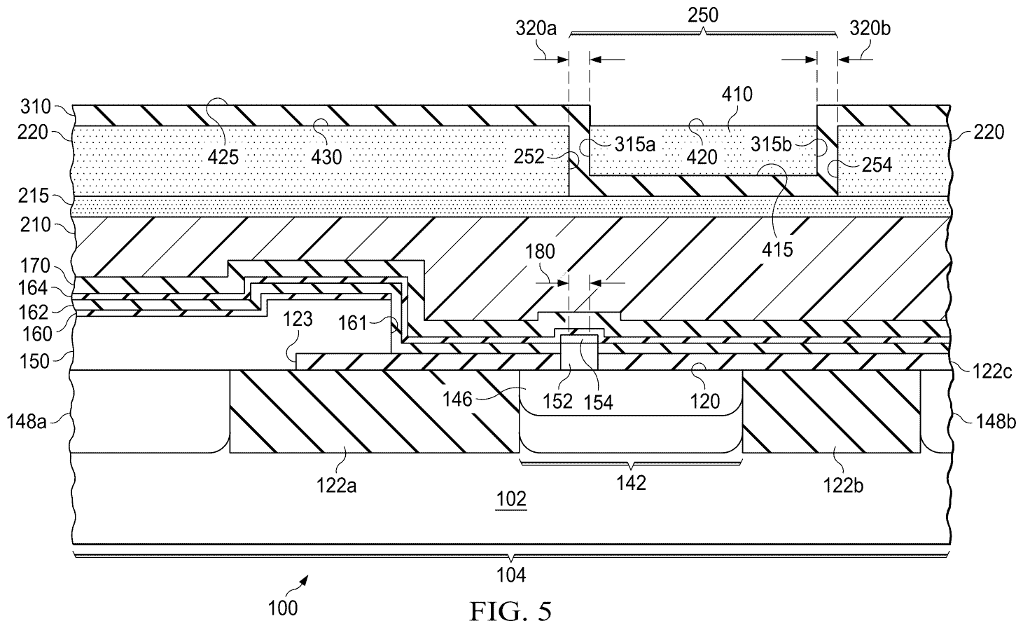

Referring to FIG. 5, a controlled thickness of sacrificial layer 410 is removed, such that sacrificial layer 410 completely covers the outward facing surface 415 of spacer layer 310 within opening 250 yet is not coplanar with an outward facing surface of spacer layer 310 outside of opening 250. In some examples, an etch may be performed using an endpoint that detects exposure of the spacer layer 310 (e.g., an 02 etch with an endpoint on oxide).

As shown in FIG. 5, the remaining portion of sacrificial layer 410 within opening 250 may have an outward facing surface 420 that is substantially coplanar with an outward facing surface 430 of resist layer 220, which opposes an inward facing surface of spacer layer 310.

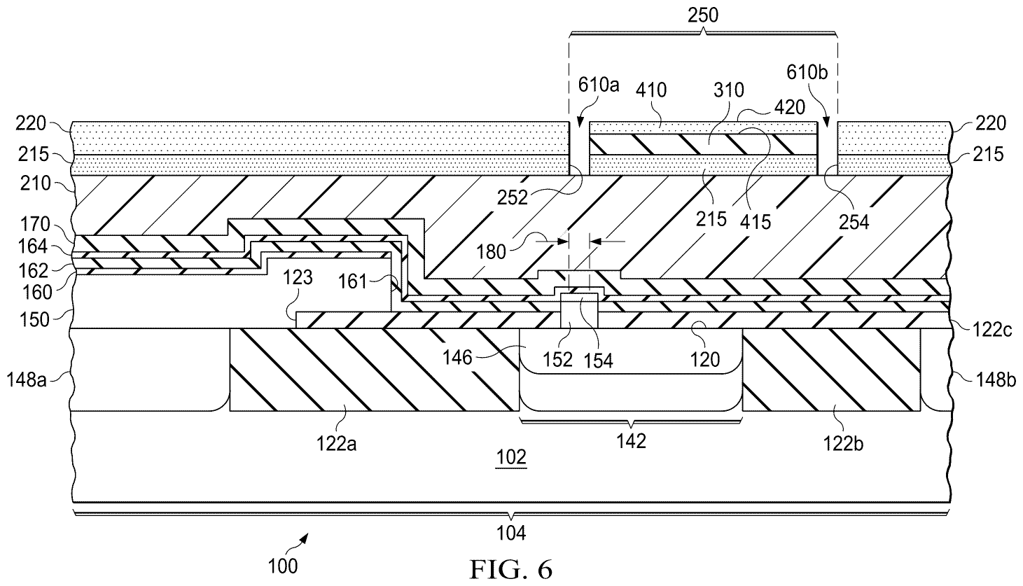

Referring to FIG. 6, the illustrated portion of spacer layer 310 is almost completely removed, with the exception of a remaining portion of spacer layer 310 underlying sacrificial layer 410, which shields the underlying portion of spacer layer 310 from the selective removal processing. In some examples, the selective removal processing may include an etch process selective to the first sacrificial layer 210.

The removal of spacer layer 310 exposes underlying portions of sacrificial layer 215. FIG. 6 further shows that the exposed portions of sacrificial layer 215 are also removed (e.g., concurrently with or subsequent to the processing used to selectively remove the exposed portions of spacer layer 310). The removal of spacer layer 310 and the underlying portions of sacrificial layer 215 results in forming linear openings 610a, 610b, which may be parallel to one another. Linear openings 610a, 610b extend vertically through respective portions of sacrificial layer 215, resist layer 220, and spacer layer 310. Linear opening 610a has sidewalls that align with corresponding respective edges of CD 180, such that the width of opening 610a corresponds to the desired finished width of CD 180. Linear opening 610a is positioned over an emitter region of the BJT, which in this example is over both BJT collector 152 and BJT base 154.

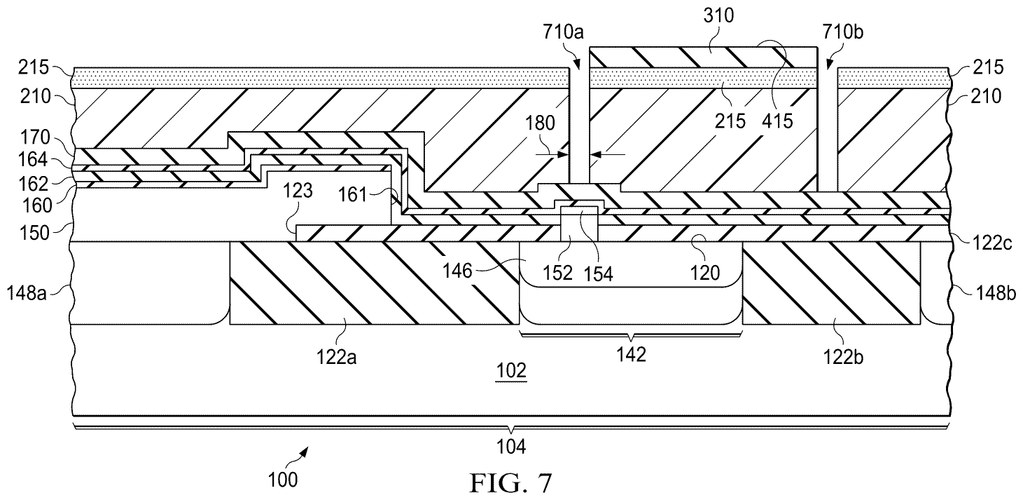

Referring to FIG. 7, respective portions of sacrificial layer 210 and resist layer 220 are selectively removed. In some examples, the selective removal processing may include an etch selective to the dielectric spacer layer 170. The selective removal extends linear openings 610a, 610b through sacrificial layer 210 to form deeper linear openings 710a, 710b, respectively. The selective removal exposes portions of sacrificial layer 215, while a portion of spacer 310 between linear openings 710a, 710b protects an underlying portion of sacrificial layer 215 from the etch process. Linear opening 710a is positioned over the emitter region of the BJT, which in this example is over both BJT collector 152 and BJT base 154. Although not shown in FIG. 7, in some examples, all or a portion of second sacrificial layer 215 may be removed prior to selectively removing sacrificial layer 210 and resist layer 220 to form deeper linear openings 710a, 710b.

Referring to FIG. 8, the remaining portion of spacer layer 310 (between linear openings 710a, 710b) and at least a portion of sacrificial layer 215 are removed. In some examples, the selective removal processing may include an etch process selective to the dielectric protection layer 164. The removal processing removes the exposed dielectric layer 170 exposed by the linear openings 710a, 710b, resulting in linear openings 810a, 810b, respectively. In other words, the pattern used in forming linear openings 710a, 710b is transferred to dielectric layer 170 to form linear openings 810a, 810b, respectively, therethrough. The transferred pattern used to control the selective removal of the exposed dielectric layer 170 can result in parallel sidewalls 815a, 816b that have a three-sigma LWR less than 4 nanometers, where the distance between sidewalls 815a, 815b is equivalent (or substantially equivalent) to CD 180. Linear opening 810a is positioned over the emitter region of the BJT, which in this example is over both BJT collector 152 and BJT base 154.

Referring to FIG. 9, the remaining portions of sacrificial layers 210, 215 over dielectric layer 170 in the BJT region 104 are removed. In some examples, the selective removal processing may include a selective etch or a hardmask strip. The removal processing is selective in that it has little to no effect on the dielectric layer 170, such that the outer surface of dielectric layer 170 is exposed by the removal of sacrificial layers 210, 215, with openings 910a, 910b remaining after the removal of sacrificial layers 210 and 215. Opening 910a is positioned over the emitter region of the BJT, which in this example is over both BJT collector 152 and BJT base 154. Opening 910a has parallel sidewalls 915a, 915b, each having respective linear edges that have a three-sigma LWR less than 4 nanometers. The distance between sidewalls 915a, 915b is equivalent (or substantially equivalent) to CD 180. Opening 910a has dimensions suited for the subsequent formation of portions of a BJT emitter therein, and hence over BJT collector 152 and BJT base 154.

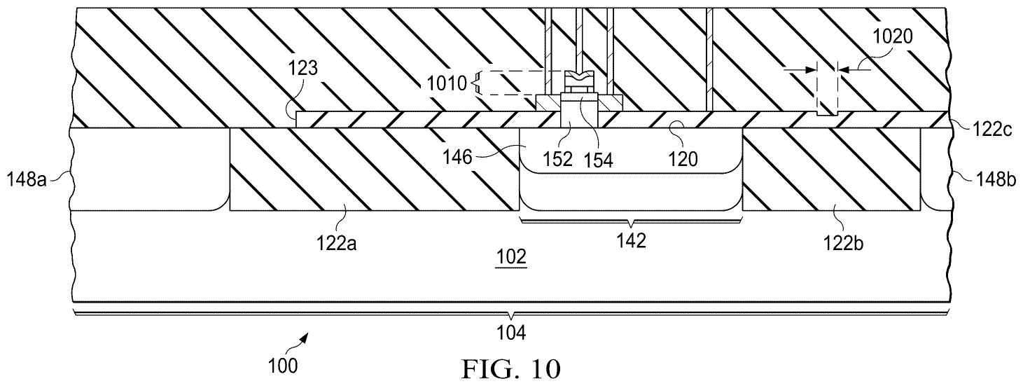

Referring to FIG. 10, a number of subsequent processing steps (e.g., as described in incorporated U.S. application Ser. No. 18/520,527 (hereinafter “the '527 application”) to form a BJT emitter 1010 over BJT collector 152 and BJT base 154. Notably, dielectric layer 170 has been completely removed from the BJT region 104. In some examples, the removal of dielectric layer 170 can result in a slight recess 1020 within isolation structure portion 122c corresponding to opening 910b of FIG. 9. The recess 1020 may extend in a frame-like pattern until it connects to first and second opposite ends of BJT emitter 1010, thereby providing a visible indication of certain processing used to form BJT emitter 1010.

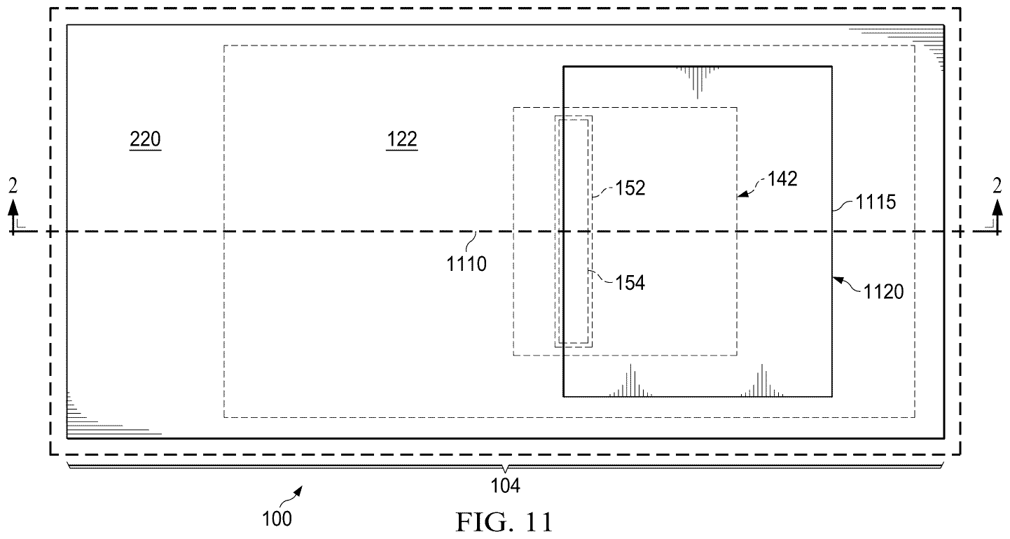

FIG. 11 is a top-down view of the semiconductor device 100 of FIG. 1 at an intermediate stage of manufacturing according to some examples. The intermediate stage of manufacturing shown in FIG. 11 corresponds to example processing that can occur after the intermediate stage of manufacturing shown in FIG. 1 and before the intermediate stage of manufacturing shown in FIG. 2, such that, at the intermediate stage of manufacturing shown in FIG. 11, multiple layers 210, 215, 220 are formed over dielectric layer 170.

As shown in FIG. 11, the BJT region 104 includes a BJT base 154 on a BJT collector 152. The BJT collector 152 and BJT base 154 both extend laterally over substrate 102. The n-type doped well 142 laterally surrounds all the outermost edges of the BJT base 154 and the BJT collector 152. The isolation structure 122 laterally surrounds all the outermost edges of the n-typed doped well 142.

Pattern 1120 shows an example emitter mask pattern (e.g., a clear mask) that can be applied to resist layer 220 and used to form opening 250 within resist layer 220 (as shown in FIG. 2). In this example, pattern 1120 is rectangular in shape. Pattern 1120 includes a linear edge 1115 that, when transferred to resist layer 220 (FIG. 2), can be used to form opening 250 having a sidewall 252 aligned the transferred pattern of linear edge 1115.

FIG. 12 provides a top-down view of a portion of the semiconductor device 100 of FIG. 1 at an intermediate stage of manufacturing according to some examples. The top-down view in FIG. 12 may correspond to the cross-sectional view of FIG. 3, which shows the spacer layer 310 formed conformally over resist layer 220, including within opening 250. While FIG. 3 shows spacer layer 310 extending past the sidewalls of opening 250 (including sidewall 252) on an outer surface of resist layer, for the ease of reference, FIG. 12 illustrates only the portion of spacer 310 corresponding to thickness 320.

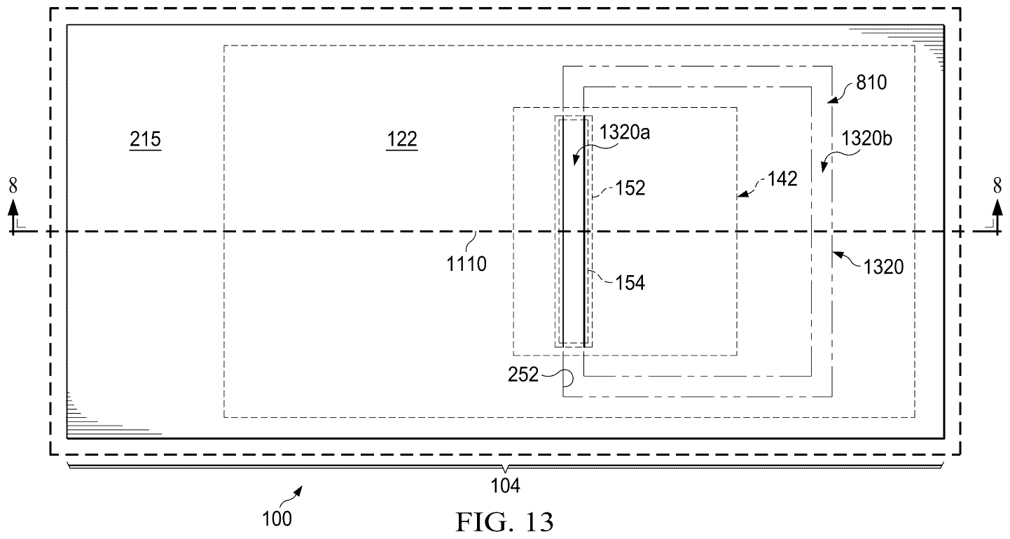

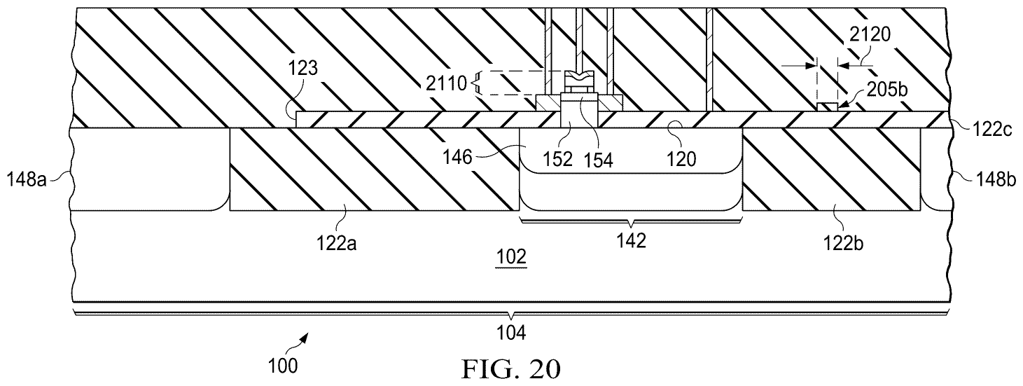

FIG. 13 provides a top-down view of a portion of the semiconductor device 100 of FIG. 1 at an intermediate stage of manufacturing according to some examples. The top-down view in FIG. 13 shows a representation of a pattern 1320 transferred to dielectric layer 170 as a result of the selective etch of exposed portions thereof, for example as shown in FIG. 8. A first linear portion 1320a of the transferred pattern 1320 can be used subsequently in forming a BJT emitter (e.g., BJT emitter 1010 of FIG. 10 or BJT emitter 2110 of FIG. 20). A second portion 1320b of the transferred pattern 1320 is connected to first and second opposite ends of the first portion 1320a. The second portion 1320b of the transferred pattern 1320 is sacrificial and is removed at some point in the manufacturing.

In some examples, including those described with reference to FIGS. 1 through 10, the first portion 1320a of the transferred pattern 1320 defines the width of an opening (e.g., opening 810a of FIG. 8) patterned in dielectric layer 170. In some other examples, including those described with reference to FIGS. 1 through 3 and 14 through 19, the first portion 1320a of the transferred pattern 1320 defines the width of a solid line (e.g., strip 205a of FIG. 19) patterned in dielectric layer 170, which is part of a frame-shaped structure. Regardless of whether the transferred pattern 1320 is used to form an opening or a solid line or frame in dielectric layer 170, the linear edges of the first portion 1320a of the transferred pattern 1320 may have a three-sigma LWR less than 4 nanometers. In instances, where the transferred pattern 1320 is used to form an opening in dielectric layer 170, an over-etch of the portion of the dielectric layer 170 corresponding to the second portion 1320b of the transferred pattern 1320 can result in creating a recess 1020 as illustrated in FIG. 10. In alternative instances, where the transferred pattern 1320 is used to form a solid line or frame in dielectric layer 170, a slight under-etch of the portion of the dielectric layer 170 corresponding to the second portion 1320b of the transferred pattern 1320 can result in creating a slightly raised frame-shaped portion 2120, or mesa, over isolation structure layer 122, as shown by raised portion 2120 of FIG. 20.

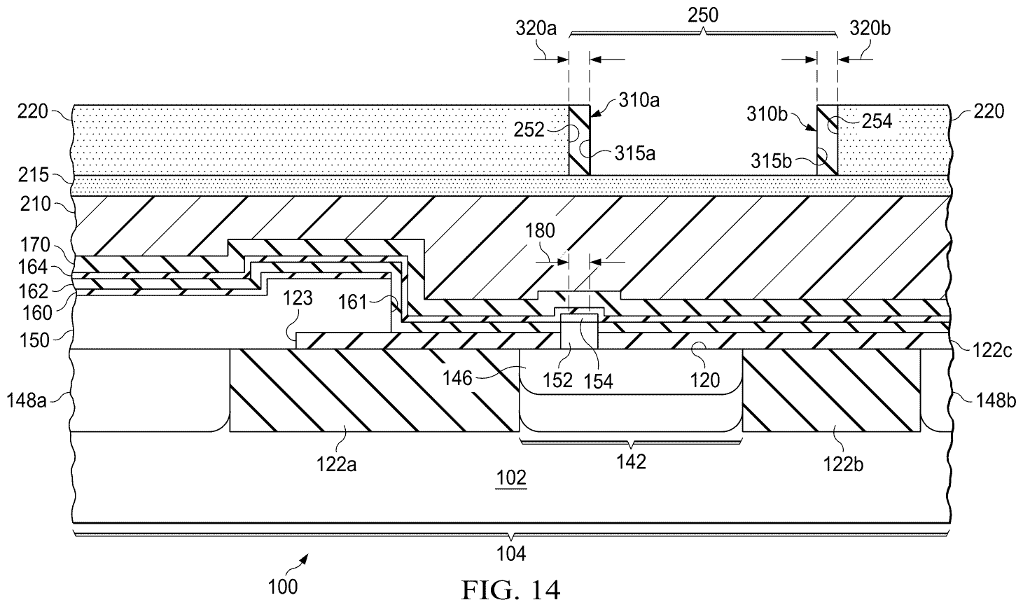

FIGS. 14 through 20 are respective cross-sectional views of a portion of a semiconductor device 100 at intermediate stages of manufacturing according to some examples. The intermediate stages of manufacturing described with reference to FIGS. 1 through 3 are performed as previously described. Unlike the intermediate stages of manufacturing shown in FIGS. 4 through 10, however, FIGS. 14 through 20 show respective intermediate stages of manufacturing involving the transfer of a pattern to dielectric layer 170 in which CD 180 defines the width of a solid line (e.g., strip 205a of FIG. 19) patterned in dielectric layer 170.

Referring to FIG. 14, the spacer layer 310 outside of opening 250 and the portion lining the base of opening 250 is removed, leaving behind the portion of spacer corresponding to spacer layer strips 310a and 310b. In some examples, the selective removal processing may include a selective etch. The remaining portions of spacer layer 310 includes sidewalls 315a, 315b lining opposing sides of the opening 250 in resist layer 220, such that sidewalls 315a, 315b are two opposite sidewalls of a four-sided contiguous frame-like pattern (e.g., as shown more clearly in the top-down view of FIG. 12). Sidewall 315a of spacer layer 310 is spaced apart from sidewall 252 of resist layer 220, such that the thickness of the portions lining opening 250 is represented by thicknesses 320a, 320b. Sidewalls 252 and 315a are positioned to align with corresponding respective edges of CD 180, such that the thickness 320a of spacer layer 310 corresponds to CD 180.

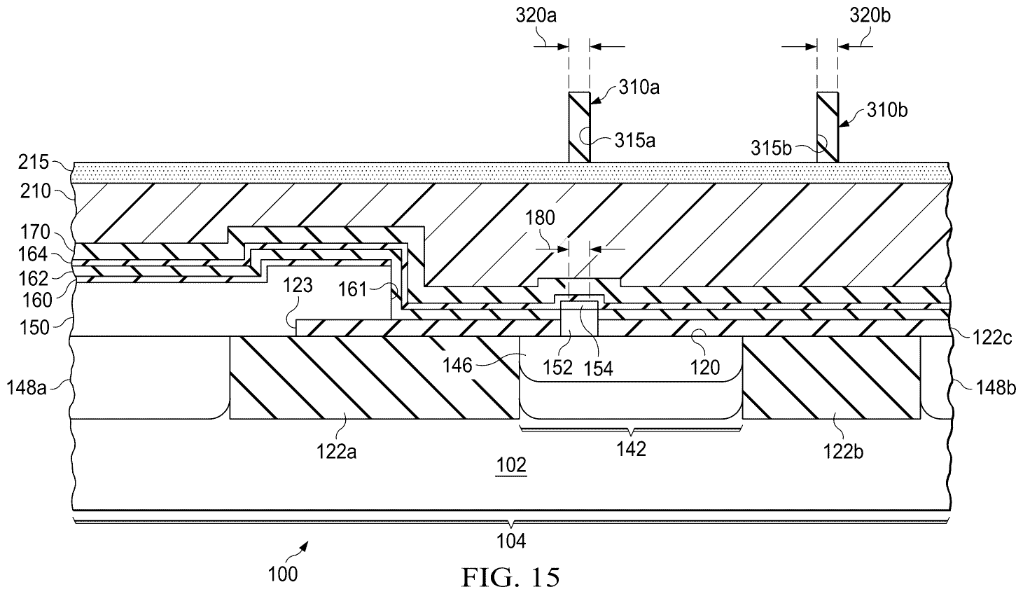

Referring to FIG. 15, the resist layer 220 is removed, thereby exposing an outer surface of sacrificial layer 215. In some examples, the removal of resist layer 220 may include a resist strip. As shown in FIG. 15, spacer layer strips 310a, 310b extend vertically from sacrificial layer 215 and are freestanding (i.e., no longer in contact with resist layer 220). The spacer layer strips 310a and 310b are parallel to one another and are part of a contiguous, frame-like structure patterned as shown by width 320 of FIG. 12. Spacer layer strip 310a is located to align with corresponding respective edges of CD 180, such that the thickness of spacer layer strip 310a is equivalent to (or is substantially equivalent to) CD 180.

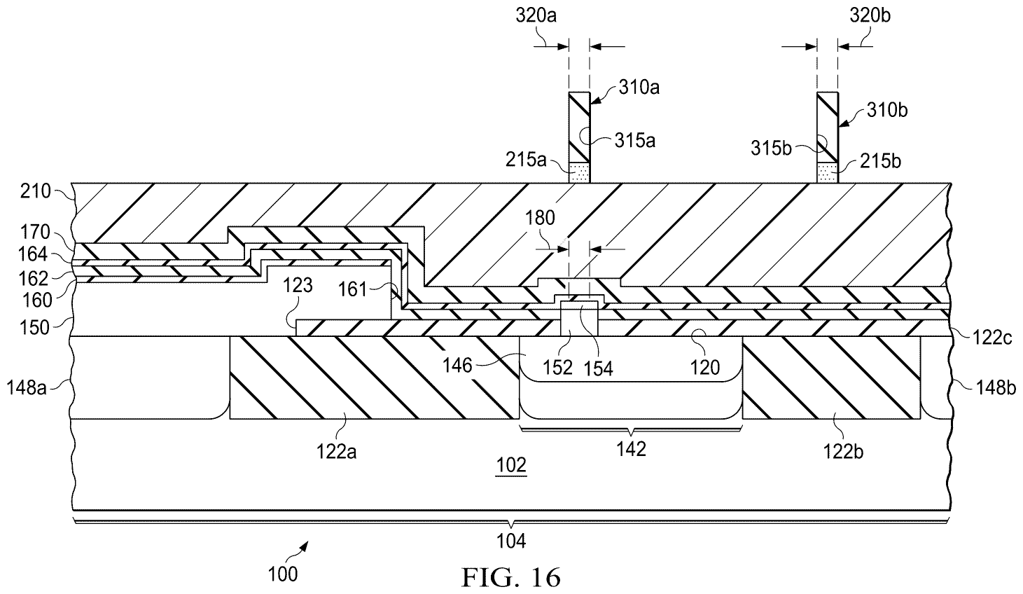

Referring to FIG. 16, the exposed portions of sacrificial layer 215 are removed. In some examples, the removal processing may include a selective etch. The portion of sacrificial layer 215 protected by spacer layer strips 310a, 310b remains after the sacrificial removal, such that the frame-like pattern including spacer layer strips 310a, 310b is transferred to sacrificial layer 215, thereby forming sacrificial layer strips 215a, 215b inwardly from spacer layer strips 310a, 310b, respectively. The collective height of strips 215a, 310a and the collective height of strips 215b, 310b extend vertically from the top surface of sacrificial layer 210.

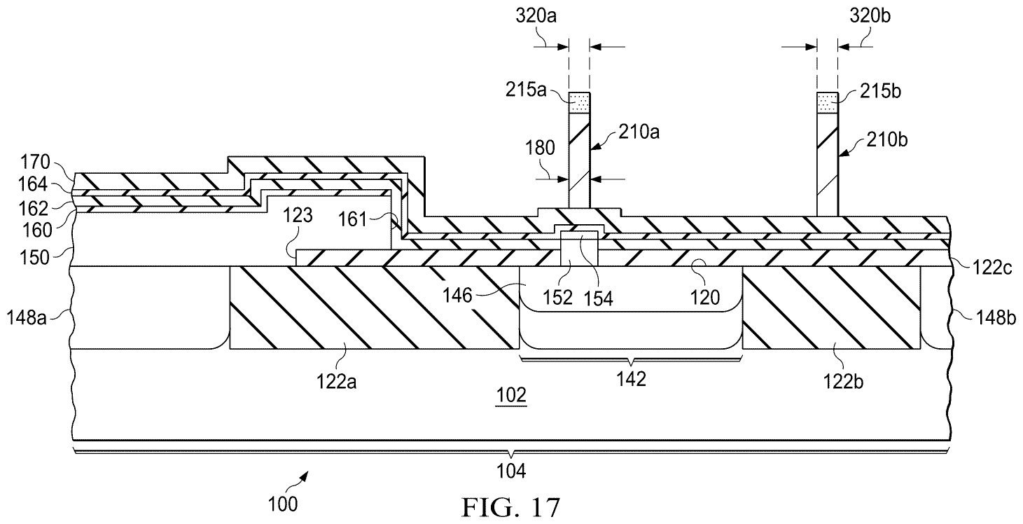

Referring to FIG. 17, the remaining portions of spacer layer 310 (e.g., spacer layer strips 310a, 310b) and the exposed portions of sacrificial layer 210 are removed. In some examples, the selective removal processing may include a selective etch. The portion of sacrificial layer 210 protected by sacrificial layer strips 215a, 215b remains after the sacrificial removal, such that the frame-like pattern including sacrificial layer strips 215a, 210b is transferred to sacrificial layer 210, thereby forming sacrificial layer strips 210a, 210b inwardly from sacrificial layer strips 215a, 215b, respectively. The collective vertical length of strips 210a, 215a and the collective vertical length of strips 210b, 215b both extend vertically from an outer surface of sacrificial layer dielectric layer 170.

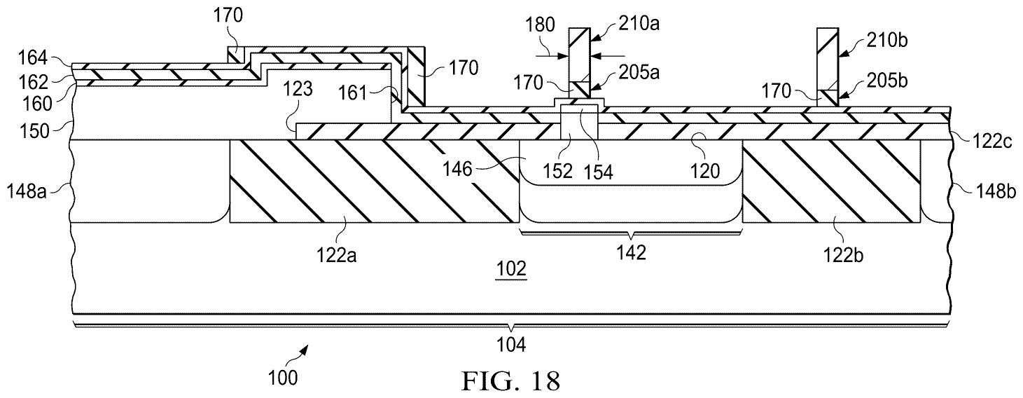

Referring to FIG. 18, the remaining portion of sacrificial layer 215 is removed and selective portions of dielectric layer 170 are removed. In some examples, the selective removal processing may include a selective etch. The portion of dielectric layer 170 protected by sacrificial layer strips 210a, 210b remains after the removal, such that the frame-like pattern including sacrificial layer strips 210a, 210b is transferred to dielectric layer 170, thereby forming strips 205a, 205b colinear with sacrificial layer strips 210a, 210b, respectively. The collective height of strips 205a, 210a and the collective height of strips 205a, 210b both extend vertically from the top surface of sacrificial layer dielectric layer 170. As shown in FIG. 18, portions of dielectric layer 170 not protected by sacrificial layer 210 may remain as a result of the selective removal of portions of dielectric layer 170.

Referring to FIG. 19, the remaining portion of sacrificial layer 210 (e.g., sacrificial layer strips 210a, 210b) is completely removed. In some examples, the selective removal processing may include a selective etch or a hardmask strip. The removal leaves behind sacrificial layer strips 210a, 210b, having a frame-like pattern that is the result of the transfer of patterns heretofore described.

Referring to FIG. 20, a number of subsequent processing steps (e.g., as described in the '527 application) to form a BJT emitter 2010 over BJT collector 152 and BJT base 154. In some examples, the processing used to form BJT emitter 2010 may result in slightly raised pattern extending vertically from the top surface of the isolation structure 122 and having a width represented as width 2020. The raised pattern, or mesa, may be part of a frame-like pattern extending laterally over a surface of isolation structure 122, where the frame-like pattern adjoins first and second opposite ends of BJT emitter 2010 (e.g., as shown by the second portion 1320b of FIG. 13). Thus, raised pattern can provide a visible indication of certain processing used to form BJT emitter 2010.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context. To aid the Patent Office, and any readers of any patent issued on this application, in interpreting the claims appended hereto, applicant notes that there is no intention that any of the appended claims invoke 35 U.S.C. § 112(f) as it exists on the date of filing hereof unless the words “means for” or “step for” are explicitly used in the claim language.

In the foregoing descriptions, for purposes of explanation, numerous specific details are set forth to provide a thorough understanding of one or more examples. However, this disclosure may be practiced without some or all these specific details, as will be evident to one having ordinary skill in the art. In other instances, well-known process steps or structures have not been described in detail in order not to unnecessarily obscure this disclosure. In addition, the foregoing description is not intended to limit the disclosure to the described examples. To the contrary, the description is intended to cover alterations, modifications, substitutions, and equivalents as may be included without departing from the scope defined by the appended claims.

What is claimed is:

1. A method of forming an electronic device, comprising:
receiving a semiconductor substrate having a dielectric layer located over an emitter region of a partially formed bipolar junction transistor;
forming a sacrificial layer over the dielectric layer;
forming a resist layer over the sacrificial layer;
forming a first pattern in the resist layer including a resist layer sidewall over the emitter region;
forming a second pattern in the sacrificial layer, the second pattern including a sacrificial layer sidewall aligned with the resist layer sidewall; and
transferring the second pattern to the dielectric layer.

2. The method of claim 1, wherein the second pattern includes an opening in the dielectric layer, the opening including first and second dielectric layer sidewalls over the emitter region.

3. The method of claim 1, wherein the second pattern includes a portion of the dielectric layer having first and second dielectric layer sidewalls over the emitter region.

4. The method of claim 1, wherein the dielectric layer is a first dielectric layer and the first pattern includes an opening in the resist layer, and further comprising forming a conformal second dielectric layer over the resist layer, the second dielectric layer having dielectric sidewall portions on sidewalls of the opening.

5. The method of claim 4, further comprising removing the sidewall dielectric portions thereby exposing the sacrificial layer.

6. The method of claim 5, further comprising removing the exposed sacrificial layer thereby exposing a portion of the first dielectric layer, and then removing the exposed portion of the first dielectric layer.

7. The method of claim 6, wherein the exposed portion of the first dielectric layer is over a dielectric isolation region extending into the semiconductor substrate.

8. The method of claim 4, further comprising removing a bottom portion of the second dielectric layer between the dielectric sidewall portions, thereby forming sidewall spacers on the sidewalls of the resist layer and exposing a portion of the sacrificial layer.

9. The method of claim 8, further comprising removing the exposed sacrificial layer, thereby exposing a portion of the first dielectric layer, the sidewall spacers masking a remaining portion of the sacrificial layer.

10. The method of claim 9, further comprising removing the exposed portion of the first dielectric layer, the remaining portion of the sacrificial layer masking a remaining portion of the first dielectric layer having first and second sidewalls over the emitter region.

11. An integrated circuit, comprising:
a semiconductor substrate;
a bipolar junction transistor over the substrate, the bipolar junction transistor having a collector having a first conductivity type over the substrate, and a base having an opposite second conductivity type over the collector;
a dielectric layer extending over the base;
an emitter over the base and extending through an opening in the dielectric layer, the emitter having first and second ends; and
a pattern extending from one or both of the first and second ends, the pattern including an edge extending laterally over the semiconductor substrate.

12. The integrated circuit of claim 11, wherein the emitter and the pattern form a closed loop.

13. The integrated circuit of claim 11, wherein the pattern forms a mesa above a top surface of the dielectric layer abutting the pattern.

14. The integrated circuit of claim 11, wherein the pattern is recessed relative to a top surface of the dielectric later abutting the pattern.

15. A method of forming an integrated circuit, comprising:
forming a material stack over a substrate including a first doped region having a first conductivity type located over a second doped region having a second conductivity type, the material stack including a first material layer, a second material layer over the first material layer, and a third material layer over the second material layer;
forming a first opening through the third material layer, the first opening having a sidewall over the first doped region;
forming a fourth material layer over the third material layer and extending into the opening, a sidewall portion of the fourth material layer located over the sidewall;
forming a fifth material layer within the opening, the sidewall portion between the sidewall and the fifth material layer; and
removing the sidewall portion, thereby forming a second opening over the first doped region.

16. The method of claim 15, wherein the first doped region has a first width and the second opening has a second width less than the first width.

17. The method of claim 15, wherein the sidewall is a first sidewall, and the second opening has third and fourth sidewalls over the first doped region.

18. The method of claim 15, wherein the second opening forms a closed loop including a portion over and parallel to the first doped region.

19. The method of claim 15, further comprising removing the first material layer exposed by the second opening, thereby exposing a dielectric layer located over and touching the second doped region.

20. The method of claim 19, wherein exposing the dielectric layer exposes a first portion of the dielectric layer directly over the first doped region, and a second portion of the dielectric layer laterally spaced apart from the first portion.
